(19) United States
(12) Patent Application Publication
(10) Pub. No.: US 2006/0035176 A1
(43) Pub. Date: Feb. 16, 2006

(54) Photoresist stripping solution and a method of stripping photoresists using the same

(76) Inventors: Shigeru Yokoi, Kanagawa-ken (JP); Kazumasa Wakiya, Kanagawa-ken (JP)

Correspondence Address: WENDEROTH, LIND & PONACK, L.L.P., 2033 K STREET N. W., SUITE 800, WASHINGTON, DC, 20006-1021, US

(21) Appl. No.: 11/246,297

(22) Filed: Oct. 11, 2005

Related U.S. Application Data
(63) Continuation of application No. 10/968,910, filed on Oct. 21, 2004, now abandoned.
Application No. 10/968,910 is a continuation of application No. 10/231,136, filed on Aug. 30, 2002, now abandoned.

(30) Foreign Application Priority Data
Aug. 31, 2001 (JP) 2001-264294

(51) Int. Cl. G03F 7/32

(52) U.S. Cl. 430/331

(57) ABSTRACT

A photoresist stripping solution comprising (a) a carboxyl group-containing acidic compound, (b) at least one basic compound (for example, monoethanolamine, tetraalkylammonium) selected from among alkanolamines and specific quaternary ammonium hydroxides, (c) a sulfur-containing corrosion inhibitor and (d) water, and having a pH value of 3.5-5.5; and a method of stripping photoresists using the same are disclosed. The present invention provides a photoresist stripping solution which is excellent in the effect of protecting metal wirings (in particular, Cu wirings) from corrosion, never damages interlevel films, such as low dielectric layers or organic SOG layers, and shows excellent strippability of photoresist films and post-ashing residues.

This application is a continuation of U.S. application Ser. No. 10/968,910, filed Oct. 21, 2004, now abandoned, which is a continuation of U.S. application Ser. No. 10/231,136, filed Aug. 30, 2002, now abandoned.

### BACKGROUND OF THE INVENTION

1. Field of the Invention

This invention relates to a photoresist stripping solution and a method of stripping photoresists using the same. More particularly, it relates to a photoresist stripping solution which is excellent in stripping photoresist films and post-ashing residues, as well as in protecting from corrosion or damage substrates having metal wiring conductors, in particular, copper (Cu) wiring conductors formed thereon or substrates having both metal wiring conductors and interlevel films formed thereon. The invention also relates to a method of stripping photoresists using the stripping solution. The present invention is suitable for use in the fabrication of semiconductor devices such as ICs and LSIs, as well as liquid-crystal panel apparatus.

2. Description of Relevant Art

The fabrication of semiconductor devices such as ICs and LSIs, as well as liquid-crystal panel apparatus, comprises forming a uniform photoresist coating over conductive metallic layers, insulation layers such as an SiO₂ film formed on a substrate (silicon wafer) by CVD; performing selective exposure and development to form a photoresist pattern; selectively etching the substrate having the conductive metallic layers, the insulation layers formed thereon by CVD, using the photoresist pattern as a mask to thereby form a microcircuit; and then removing the unwanted photoresist layer with a stripping solution.

With the recent tendency toward highly integrated, high-density circuits, dry etching enabling fine etching with a higher density has become the major means. Also, it has been a practice to employ plasma ashing to remove the unnecessary photoresist layers remaining after etching. After these etching and ashing treatments, residues comprising modified photoresist films and other components, referred to horn-like shaped “veil”, “fences” or “side-walls”, remain on the bottom or side wall of patterned grooves. In addition, etching of metallic layers and ashing treatment builds up metal depositions. Such post-ashing residues or depositions should be completely stripped away so as to keep good yields in the production of semiconductors.

In particular, as the degree of integration of semiconductor devices increases and the chip size decreases, efforts are recently being made to reduce the feature size of wiring circuits while fabricating them in an increasing number of superposed layers. A problem with this approach is that wiring delay is caused by the resistance of the metal films used (wiring resistance) and wiring capacity. To deal with this problem, it has been proposed to use metals such as copper (Cu) that have smaller resistance than aluminum (Al) mainly used as a conventional wiring material, and recent models of semiconductor devices can be divided into two types, one using Al conductors (Al, Al alloy and other Al-based metal wiring) and the other using Cu conductors (Cu-based metal wiring). In addition to the need to prevent devices of these two types from corroding, it is also required to provide effective protection against corrosion of other metals on the devices, and further improvements are desired to achieve effective stripping away of the photoresist layer and the post-ashing residues, and to prevent metal conductors from corrosion.

Moreover, in the current photolithographic technology, the photoresist stripping techniques are required to meet increasingly rigorous conditions in order to adjust for the decreasing feature size of patterns, the formation of more interlevel layers on the substrate and the changes in materials formed on the substrate surface, and that it is also required to strictly control pH values of photoresist stripping solutions.

Under these circumstances, from the points of photoresist strippability and protection of substrates from corrosion, various stripping solutions have been proposed that contain acidic compounds or basic compounds

As the stripping solutions that contain acidic compounds, those containing hydrofluoric acid as the main component may be exemplified: JP-A-9-197681 proposes a resist stripping solution composition of pH 5-8 containing a salt of hydrofluoric acid with a metal-free base, a water-soluble organic solvent and water, optionally together with a corrosion inhibitor. The composition in JP-A-9-197681 is to a certain extent effective in strippability and anti-corrosivity on semiconductor devices having Al wiring conductors, however, it fails to exert any satisfactory effect of protecting devices having Cu wiring conductors from corrosion.

As the stripping solutions that contain basic compounds, on the other hand, those containing amines such as hydroxylamine as the main component may be exemplified: JP-A-6-266119 proposes a cleaner composition containing hydroxylamine, an alkanolamine and a chelating agent (a corrosion inhibitor) such as cathecol. The composition in JP-A-6-266119 is to a certain extent effective in strippability and anti-corrosivity on semiconductor devices having Al wiring conductors, however, it fails to exert any satisfactory effect of protecting devices having Cu wiring conductors and interlevel films from corrosion and damage.

In addition to those described above, there have been proposed an alkali-containing photoresist stripping solution containing a solvent, a nucleophilic amine and a nitrogen-free weak acid in an amount sufficient for partly neutralizing the nucleophilic amine (JP-A-6-202345), an alkali-containing photoresist stripping solution containing a solvent having a solubility parameter of about 8 to 15, a nucleophilic amine and a reducing agent at a specific ratio (JP-A-7-219241), and a side wall-removal solution comprising an alkanolamine, an organic acid and water (JP-A-11-174690), etc. However, each of the stripping solutions in those gazettes has a pH value regulated within the alkaline region and thus cannot sufficiently protect Cu-based metal wirings from corrosion.

For inhibiting corrosion of Cu wiring conductors, JP-A-2000-273663 proposes a cleaner solution for semiconductor devices that contains at least one sulfur-containing corrosion inhibitor having mercpto group together with an alkali or an acid. However, even in using the cleaner solution in JP-A-2000-273663, it is still insufficient in protecting Cu wiring conductors and low dielectric films (interlevel films) from corrosion, and in stripping photoresists and post-ashing residues in the treatment of stripping photoresists in semiconductor devices employed today that requires a strict pH control.

Thus, it is very difficult by using the conventional stripping solutions to achieve both of the protection of substrates having metal wirings (in particular, Cu wirings) formed thereon or substrates having both metal wirings and interlevel films formed thereon from corrosion or damage, and favorable strippability of photoresist films and post-ashing residues in a well-balanced manner in the photoresist stripping technology for semiconductor devices today that requires strict pH control.

### SUMMARY OF THE INVENTION

It is an object of the present invention to provide a photoresist stripping solution which is excellent in protecting substrates having metal wiring conductors (in particular, Cu wiring conductors) formed thereon or substrates having both metal wiring conductors and interlevel films formed thereon from corrosion or damage, and in stripping photoresist films and post-ashing residues.

It is another object of the present invention to provide a method of stripping photoresists using the above photoresist stripping solution.

To attain the above-described object, the present invention provides a photoresist stripping solution comprising (a) a carboxyl group-containing acidic compound, (b) at least one basic compound selected from among alkanolamines and quaternary ammonium hydroxides represented by the following general formula (I): 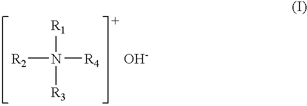
wherein R₁, R₂, R₃ and R₄ are each independently an alkyl group or a hydroxyalkyl group having 1-5 carbon atoms, (c) a sulfur-containing corrosion inhibitor and (d) water, and having a pH value of 3.5-5.5.

The present invention further provides a method of stripping photoresists comprising forming a photoresist pattern on a substrate, etching the substrate using the photoresist pattern as a mask, and thereafter stripping away the photoresist pattern from the substrate using the photoresist stripping solution as described above.

The present invention furthermore provides a method of stripping photoresists comprising forming a photoresist pattern on a substrate, etching the substrate using the photoresist pattern as a mask, then plasma ashing the photoresist pattern, and thereafter stripping away post-ashing residues from the substrate using the photoresist stripping solution as described above.

### DETAILED DESCRIPTION OF THE INVENTION

The present invention will be described below in detail.

As the carboxyl group-containing acidic compound as component (a) in the present invention, it is preferable to use a carboxylic acid containing an alkyl group or a hydroxyalkyl group having 1-5 carbon atoms. Examples thereof include acetic acid, propionic acid, butyric acid, isobutyric acid and glycolic acid. Among all, acetic acid is particularly preferred in point of protecting Cu wiring conductors from corrosion. Either one or more compounds may be used as component (a).

The content of component (a) preferably ranges in an amount of 2-20 mass percent, more preferably 5-15 mass percent. In case where component (a) is too small, the strippability of photoresists or post-ashing residues is liable to be lowered.

Component (b) is at least one basic compound selected from among alkanolamines and quaternary ammonium hydroxides represented by the following general formula (I): 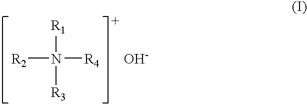
wherein R₁, R₂, R₃ and R₄ are each independently an alkyl group or a hydroxyalkyl group having 1-5 carbon atoms.

Examples of the alkanolamines include monoethanolamine, diethanolamine, triethanolamine, 2-(2-aminoethoxy)ethanol, N,N-dimethylethanolamine, N,N-diethylethanolamine, N,N-dibutylethanolamine, N-methylethanolamine, N-ethylethanolamine, N-butylethanolamine, N-methyldiethanolamine, monoisopropanolamine, diisopropanolamine and triisopropanolamine. Among all, monoethanolamine, N-methylethanolamine, etc. are preferred in point of protecting Cu wiring conductors from corrosion.

Specific examples of the quaternary ammonium hydroxides represented by the general formula (I) include tetramethylammonium hydroxide(=TMAH), tetraethylammonium hydroxide, tetrapropylammonium hydroxide, tetrabutylammonium hydroxide, monomethyltripropylammonium hydroxide, trimethylethylammonium hydroxide, (2-hydroxyethyl)trimethylammonium hydroxide, (2-hydroxyethyl)triethylammonium hydroxide, (2-hydroxyethyl)tripropylammonium hydroxide and (1-hydroxypropyl)trimethylammonium hydroxide. Among all, TMAH, tetraethylammonium hydroxide, tetrapropylammonium hydroxide, tetrabutylammonium hydroxide, monomethyltripropylammonium hydroxide, (2-hydroxyethyl)trimethylammonium hydroxide, etc. are preferred because of the easiness in availability and high safety.

As component (b), either one or more compounds may be used. The content of component (b) preferably ranges in an amount of 2-20 mass percent, more preferably 5-15 mass percent. In case where component (b) is too small, the strippability of in particular post-ashing residues is liable to be lowered.

Examples of the sulfur-containing corrosion inhibitor as component (c) include dithiodiglycerol [S(CH₂CH(OH)CH₂(OH))₂], bis(2,3-dihydroxypropylthio)ethylene [CH₂CH₂(SCH₂CH(OH)CH₂(OH))₂], sodium 3-(2,3-dihydroxypropylthio)-2-methyl-propylsulfonate [CH₂(OH)CH(OH)CH₂SCH₂CH(CH₃)CH₂SO₃Na], 1-thioglycerol [HSCH₂CH(OH)CH₂(OH)], sodium 3-mercapto-1-propanesulfonate [HSCH₂CH₂CH₂SO₃Na], 2-mercaptoethanol [HSCH₂CH₂(OH)], thioglycolic acid [HSCH₂CO₂H] and 3-mercapto-1-propanol [HSCH₂CH₂CH₂OH]. Among all, 1-thioglycerol, sodium 3-mercapto-1-propanesulfonate, 2-mercaptoethanol and 3-mercapto-1-propanol, etc. are preferred. In particular, 1-thioglycerol is most preferred. As component (c), either one or more compounds may be used.

The content of component (c) preferably ranges in an amount of 0.05-5 mass percent, more preferably 0.1-0.2 mass percent. In case where component (c) is too small, it is feared that metal wirings such as Cu wirings cannot be effectively protected from corrosion.

As component (d), water is used in an amount of the balance of total amounts of other components of the stripping solution of the invention.

The photoresist stripping solution of the present invention should be regulated to pH 3.5-5.5, preferably pH 4.0-5.0. If the pH value is less than 3.5 or exceeds 5.5, there arise damages such as corrosion of metal wirings (in particular, Cu wirings) or interlevel films and surface roughing.

In order to improve penetrating properties, the stripping solution of the invention may further contain, as an optional component, an acetylene alcohol/alkylene oxide adduct prepared by adding an alkylene oxide to an acetylene alcohol.

As the acetylene alcohol as described above, use may be preferably made of compounds represented by the following general formula (II): 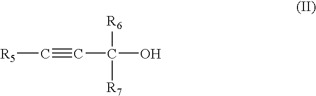
wherein R₅ is a hydrogen atom or a group represented by the following formula (III): 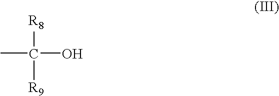
and R₆, R₇, R₈ and R₉ are each independently a hydrogen atom or an alkyl group having 1-6 carbon atoms.

These acetylene alcohols are commercially available under trade names of “Surfynol” and “Olfin” series (both are produced by Air Product and Chemicals Inc.). Among these commercial products, “Surfynol 104”, “Surfynol 82” or mixtures thereof are most preferred for the physical properties. Use can be also made of “Olfin B”, “Olfin P”, “Olfin Y” etc.

As the alkylene oxide to be added to the acetylene alcohol as described above, it is preferable to use ethylene oxide, propylene oxide or a mixture thereof.

In the present invention, it is preferable to use, as the acetylene alcohol/alkylene oxide adduct, compounds represented by the following general formula (IV): 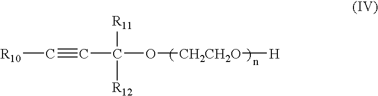
wherein R₁₀ is a hydrogen atom or a group represented by the following formula (V): 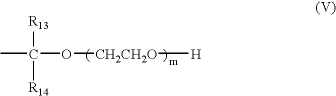
and R₁₁, R₁₂, R₁₃ and R₁₄ are each independently a hydrogen atom or an alkyl group having 1-6 carbon atoms; (n+m) is an integer of 1 to 30, which is the number of ethylene oxide molecules added. This number subtly affects the properties of the compound such as water solubility and surface tension.

The acetylene alcohol/alkylene oxide adducts per se are known as surfactants. These products are commercially available under the trade names of “Surfynol” series (products of Air Product and Chemicals Inc.) and “Acetylenol” series (products of Kawaken Fine Chemicals Co., Ltd.) and have been appropriately utilized. Among these products, it is preferred to use “Surfynol 440” (n+m=3.5), “Surfynol 465” (n+m=10), “Surfynol 485” (n+m=30), “Acetylenol EL” (n+m=4), “Acetylenol EH” (n+m=10) or mixtures thereof, in view of the changes in their physical properties such as water solubility and surface tension depending on the number of ethylene oxide molecules added. A mixture of “Acetylenol EL” with “Acetylenol EH” in a mass ratio of 2:8 to 4:6 is particularly desirable.

Use of the acetylene alcohol/alkylene oxide adduct makes it possible to improve the penetrating properties and wetting properties of the stripping solution. Therefore, in forming hole patterns, the stripping solution spreads widely over the side walls of the patterned grooves. This is a possible reason why the stripping solution effectively improve strippability for the ultra-fine patterns of about 0.2-0.3 μm in line width.

When the stripping solution of the invention contains the acetylene alcohol/alkylene oxide adduct, the content thereof is preferably 0.05-5 mass percent, more preferably 0.1-2 mass percent. When the content exceeds the upper limit as defined above, it tends to cause foaming but the wetting properties cannot be improved any more. When the content is less than the lower limit as defined above, on the other hand, the desired improvement in the wetting properties can be scarcely obtained.

The photoresist stripping solution of the invention can advantageously be used with all photoresists, whether negative- or positive-working, that can be developed with aqueous alkaline solutions. Such photoresists include, but are not limited to, (i) a positive-working photoresist containing a naphthoquinonediazide compound and a novolak resin, (ii) a positive-working photoresist containing a compound that generates an acid upon exposure, a compound that decomposes with an acid to have a higher solubility in aqueous alkali solutions, and an alkali-soluble resin, (iii) a positive-working photoresist containing a compound that generates an acid upon exposure and an alkali-soluble resin having a group that decomposes with an acid to have a higher solubility in aqueous alkali solutions, and (iv) a negative-working photoresist containing a compound that generates an acid upon illumination with light, a crosslinker and an alkali-soluble resin.

According to the invention, photoresists are stripped away by one of two methods which have the following steps in common: forming a photoresist pattern by lithography on a substrate having conductive metallic layers, interlevel layers thereon, and selectively etching the layers with the photoresist pattern used as a mask to form a fine-line circuit. After these steps, the photoresist pattern is immediately stripped away (method I), or the etched photoresist pattern is subjected to plasma ashing and thereby post-ashing residues, such as the modified photoresist film (photoresist film residue) and metal deposition, are stripped away (method II).

An example of method I in which the photoresist film is stripped away immediately after etching comprises:

(I) providing a photoresist layer on a substrate;

(II) selectively exposing said photoresist layer;

(III) developing the exposed photoresist layer to provide a photoresist pattern;

(IV) etching the substrate to form a pattern using said photoresist pattern as a mask; and

(V) stripping away the photoresist pattern from the etched substrate using the photoresist stripping solution of the present invention.

An example of method II in which the post-ashing residues are stripped away after etching comprises:

(I) providing a photoresist layer on a substrate;

(II) selectively exposing said photoresist layer;

(III) developing the exposed photoresist layer to provide a photoresist pattern;

(IV) etching the substrate to form a pattern using said photoresist pattern as a mask;

(V) plasma ashing the photoresist pattern;

(VI) stripping away the post-ashing residues from the substrate using the photoresist stripping solution of the present invention.

The specific advantages of the present invention resides in that the photoresist stripping solution has excellent effects of stripping photoresist films and post-ashing residues and protecting a substrate from corrosion in stripping away photoresists formed on a substrate having metal wiring conductors or formed on a substrate having both metal wiring conductors and interlevel films.

As the metal wirings, use may be made of aluminum (Al) wirings, copper (Cu) wirings and so on. The present invention exhibits an increasingly anti-corrosion effect particularly in Cu wirings.

The term “Cu wirings” as used herein encompasses Cu alloy wirings which contain Cu as the major component together with other metal(s) (for example, Al—Si—Cu, Al—Cu) and pure Cu wirings.

Examples of the interlevel films include insulating films such as organic SOG films and low dielectric films, but are not limited thereto. Using the conventional stripping solutions, both of the strippability of photoresists and the protection and damage control of substrates having metal wirings (in particular, Cu wirings) formed thereon or substrates having both metal wirings and interlevel films formed thereon can be hardly achieved. According to the present invention, however, both of these effects can be successfully established.

In the second stripping method described above, residues adhere to the substrate surface after plasma ashing, such as photoresist residue (modified photoresist film) and metal deposition that have been formed during etching of the metal film. These residues are contacted by the stripping solution of the invention so that they are stripped away from the substrate surface. Plasma ashing is inherently a method for removing the photoresist pattern but it often occurs that part of the photoresist pattern remains as a modified film; the present invention is particularly effective for the purpose of completely stripping away such modified photoresist film.

In forming the photoresist layer, and exposing, developing and etching treatments, any conventional means may be employed without particular limitation.

After the development step (III) or the stripping step (V) or (VI), conventional rinsing may optionally be performed using pure water, lower alcohols, etc., followed by drying.

Depending on the type of photoresist used, post-exposure bake which is usually applied to the chemically amplified photoresist may be performed. Post bake may also be performed after forming the photoresist pattern.

The photoresist is usually stripped by the dip or shower method. The stripping time is 10-20 minutes in usual, but not limited to any duration as long as it is sufficient to achieve removal of the photoresist.

A stripping method using the stripping solution of the present invention for a substrate having a copper (Cu) wiring as a metal wiring, the following dual damascene process is typically exemplified.

Namely, a photoresist stripping method comprising:

(I) providing an etching stopper layer on a substrate having Cu wiring formed thereon and further providing an interlevel film thereover;

(II) providing a photoresist layer on the interlevel film;

(III) selectively exposing the photoresist layer;

(IV) developing the exposed photoresist layer to provide a photoresist pattern;

(V) etching the interlevel film using the photoresist pattern as a mask while leaving the etching stopper layer;

(VI) stripping away the etched photoresist pattern from the interlevel film using the photoresist stripping solution of the present invention; and

(VII) removing the remaining etching stopper layer.

In the case of performing plasma ashing, the dual damascene process is typically exemplified as follows. Namely, a photoresist stripping method comprising:

(I) providing an etching stopper layer on a substrate having Cu wiring formed thereon and further providing an interlevel film thereover;

(II) providing a photoresist layer on the interlevel film;

(III) selectively exposing the photoresist layer;

(IV) developing the exposed photoresist layer to provide a photoresist pattern;

(V) etching the interlevel film using the photoresist pattern as a mask while leaving the etching stopper layer;

(VI) plasma ashing the photoresist pattern;

(VII) stripping away the post-plasma ashing residues from the interlevel film using the photoresist stripping solution of the present invention; and

(VIII) removing the remaining etching stopper layer.

After the development step (IV) or the removing the etching stopper step (VII) or (VIII) in the above cases, conventional rinsing may be performed using pure water, lower alcohols, etc., followed by drying.

In the above-described dual damascene process, a nitride film such as an SiN film may be used as the etching stopper layer. Since the interlevel film is etched while leaving the etching stopper layer as it is, the subsequent plasma ashing treatment substantially exerts no effect on the Cu wiring.

As discussed above, the Cu wiring may be either Cu alloy wiring containing Cu as the main component together with other metal(s) such as Al or pure Cu wiring.

The stripping method by the dual damascene process in the case of including ashing treatment step may specifically be carried out as follows:

First, Cu wiring conductor is formed on a substrate, such as a silicon wafer, a glass plate, etc., and an etching stopper layer, such as an SiN film, is formed thereon, if desired. Further, an interlevel film (an organic SOG film, a low dielectric film, etc.) is formed thereover.

Next, a photoresist composition is applied onto the interlevel film, dried, exposed and developed to thereby form a photoresist pattern. The exposure and development conditions may be appropriately selected depending on the photoresist suitable for the purpose. In exposure, the photoresist layer may be exposed through a desired mask pattern to a light source emitting actinic radiations (e.g., UV light, far-UV light, excimer laser, X-rays or electron beams) such as a low-pressure mercury-vapor lamp, a high-pressure mercury-vapor lamp, an ultra-high pressure mercury-vapor lamp or a xenon lamp. Alternatively, the photoresist layer is illuminated with controlled electron beam. Thereafter, post-exposure bake is optionally performed if needed.

Then, pattern development is performed with a photoresist developer to form a predetermined photoresist pattern. The method of development is not limited to any particular type and various methods may be employed as appropriate for the specific object. Examples thereof include dip development in which the photoresist-coated substrate is immersed in the developer for a specified time and then washed with water and dried; paddle development in which the developer is dripped on the surface of the applied photoresist coat which is thereafter left to stand for a specified time, washed with water and dried; and spray development in which the photoresist surface is sprayed with the developer and thereafter washed with water and dried.

Subsequently, with the photoresist pattern used as a mask, the interlevel dielectric layer is selectively etched in such a manner as to leave the etching stopper layer, and plasma ashing to thereby remove the unwanted photoresist layer. Then the etching stopper layer remained is removed to form a fine-line circuit (hole pattern). In performing plasma ashing, post-ashing photoresist residue (modified films) and post-etching residue (metal deposition) adhering to the substrate surface can be stripped away by bringing these residues on the substrate into contact with the stripping solution of the invention.

Etching may be performed on either a wet or dry basis or two methods may be applied in combination, though it is preferred in the invention to employ dry etching.

Stripping is usually performed by dipping or spraying. It is sufficient to carry out stripping for 10 to 20 minutes in usual, though the invention is not limited thereto.

After the step of stripping as described above, the substrate is rinsed with organic solvents or water.

After forming the pattern (particularly the hole pattern) by the above-described method, Cu is buried in it by a suitable means such as plating to provide electrical continuity. If desired, the same procedure may be repeated to form an upper level comprising an interlevel dielectric layer, a hole pattern and electrical continuity so as to fabricate a multi-level Cu-wired board.

The stripping solution of the invention and the stripping method using the same have excellent effects in stripping away post-ashing photoresist films (modified films) and post-etching residue (metal deposition) even in highly integrated, high-density substrates, and, in protecting various metal conductors, metallic layers, etc. from corrosion in the step of rinsing treatment.

### EXAMPLES

The following examples are provided for the purpose of further illustrating the present invention but are in now way to be taken as limiting. Unless otherwise noted, all compounding amounts are expressed in mass percent.

### Example 1

[Treatment 1]

A silicon wafer having a Cu layer that is overlaid with a low dielectric film, formed by using a low dielectric material OCD-Type 32 (product of Tokyo Ohka Kogyo Co., Ltd.) was used as a substrate. The substrate was then spin coated with a positive-working photoresist TDUR-PO15PM (product of Tokyo Ohka Kogyo Co., Ltd.), which was prebaked at 80° C. for 90 seconds to form a photoresist layer in 0.7 μm thick.

The photoresist layer was exposed through a mask pattern using FPA 3000 EX3 (Canon Inc.), then subjected to post-exposure bake at 110° C. for 90 seconds and developed with an aqueous solution of 2.38 mass percent tetramethylammonium hydroxide (TMAH) to form a hole pattern of 200 nm in diameter. Subsequently it was subjected to dry etching, followed by plasma ashing.

The thusly treated substrate was dipped in a photoresist stripping solution shown in Table 1 (25° C., 10 minutes) for stripping and then rinsed with pure water.

Then the substrate was observed under a scanning electron microscope (SEM) to evaluate strippability of the post-ashing residues and state of corrosion of metal wiring (Cu wiring). Results are shown in Table 2.

The strippability of the post-ashing residues and state of corrosion of metal wiring (Cu wiring) were evaluated in accordance with the following criteria.

<Strippability of the Post-ashing Residues>
A: Complete stripping
B: Incomplete stripping

<State of Corrosion of Metal Wiring (Cu Wiring)>
A: No corrosion observed
B: Suffered from somewhat corrosion
C: Suffered from serious corrosion
   [Treatment II]

A silicon wafer having a low dielectric film (thickness: 200 nm) formed thereon by using a low dielectric material OCD-Type 32 (product of Tokyo Ohka Kogyo Co., Ltd.) was used as a substrate. The substrate was dipped in a photoresist stripping solution shown in Table 1 (25° C., 10 minutes) for stripping and then rinsed with pure water.

Before and after the stripping treatment, the substrate was subjected to FI-IR analysis to thereby monitor the absorption changes between before stripping treatment and after the treatment. Thus, the damage control on the low dielectric film was evaluated. The results are shown in Table 2.

The damage control on the low dielectric film was evaluated in accordance with the following criteria.

<Damage Control on the Low Dielectric Film>
A: Little change in absorption observed before and after the treatment
B: Large change in absorption observed before and after the treatment

C: No film remained due to serious loss of the low

TABLE 1

| | Photoresist stripping solution (mass %) | | | | | |
|---|---|---|---|---|---|---|
| | Component (a) | Component (b) | Component (c) | Component (d) | Other component | pH |
| Ex. 1 | acetic acid (10.0) | MEA (5.0) | 1-thioglycerol (0.4) | water | — | 4.5 |
| | | | | (balance) | | |
| Ex. 2 | acetic acid (10.0) | TMAH (7.0) | 1-thioglycerol (0.2) | water | — | 4.6 |
| | | | | (balance) | | |
| Ex. 3 | propionic acid (10.0) | MEA (7.0) | 1-thioglycerol (0.3) | water | — | 5.0 |
| | | | | (balance) | | |
| Ex. 4 | glycolic acid (5.0) | TMAH (3.5) | 1-thioglycerol (0.3) | water | — | 5.0 |
| | | | | (balance) | | |
| Ex. 5 | acetic acid (16.0) | MEA (7.0) | 1-thioglycerol (0.1) | water | — | 5.0 |
| | | | | (balance) | | |
| Ex. 6 | acetic acid (10.0) | MEA (5.0) | 1-thioglycerol (0.2) | water | acetylene | 4.5 |
| | | | | (balance) | alcohol/alkylene oxide | |
| | | | | | adduct (0.1) | |
| Com. Ex. 1 | — | MEA (6.0) | 1-thioglycerol (0.2) | water | hydrofluoric acid | 4.5 |
| | | | | (balance) | (3.0) | |
| Com. Ex. 2 | — | MEA (3.5) | 1-thioglycerol (0.1) | water | hydrochloric acid | 5.0 |
| | | | | (balance) | (2.5) | |
| Com. Ex. 3 | acetic acid (10.0) | — | 1-thioglycerol (0.2) | water | — | 2.1 |
| | | | | (balance) | | |
| Com. Ex. 4 | — | MEA (5.0) | 1-thioglycerol (0.2) | water | — | 11.5 |
| | | | | (balance) | | |
| Com. Ex. 5 | acetic acid (10.0) | MEA (1.0) | 1-thioglycerol (0.3) | water | — | 3.5 |
| | | | | (balance) | | |
| Com. Ex. 6 | acetic acid (2.5) | TMAH (10.0) | 1-thioglycerol (0.2) | water | — | 12.0 |
| | | | | (balance) | | |
| Com. Ex. 7 | acetic acid (2.9) | — | — | — | IPA (9.7), NMP(87.4) | _{—} |
| Com. Ex. 8 | acetic acid (10.0) | MEA (5.0) | — | water | IR-42 (0.1) | 4.5 |
| | | | | (balance) | | |
| Com. Ex. 9 | acetic acid (3.0) | MEA (10.0) | — | water | — | 10.0 |
| | | | | (balance) | | |

dielectric film

### Examples 2-6

By following the same procedures as in Example 1 except that each of the photoresist stripping solutions described in Table 1 was used. Then the strippability of the post-ashing residues, the state of corrosion of the Cu wiring and the damage control on the low dielectric film were evaluated each in the same manner. The results are shown in Table 2.

### Comparative Examples 1-9

By following the same procedures as in Example 1 except that each of the photoresist stripping solutions described in Table 1 was used. Then the strippability of the post-ashing residues, the state of corrosion of the Cu wiring and the damage control on the low dielectric film were evaluated each in the same manner. The results are shown in Table 2.

In Table 1, MEA stands for monoethanolamine; TMAH stands for tetramethylammonium hydroxide; IPA stands for isopropyl alcohol; NMP stands for N-methyl-2-pyrrolidone; and IR-42 stands for 2,2′-{[methyl-1H-benzotriazol-1-yl)methyl]imino}bisthenaol (IRGAMET 42).

TABLE 2

| | Treatment I | | Treatment II |
|---|---|---|---|
| | Strippability of | State of | Damage control on |
| | post-ashing | corrosion of | low dielectric |
| | residues | Cu wiring | film |
| Ex. 1 | A | A | A |
| Ex. 2 | A | A | A |
| Ex. 3 | A | A | A |
| Ex. 4 | A | A | A |
| Ex. 5 | A | A | A |
| Ex. 6 | A | A | A |
| Com. Ex. 1 | A | B | C |
| Com. Ex. 2 | A | B | A |
| Com. Ex. 3 | A | B | A |
| Com. Ex. 4 | A | B | B |
| Com. Ex. 5 | A | B | A |
| Com. Ex. 6 | A | B | B |
| Com. Ex. 7 | B | B | A |
| Com. Ex. 8 | A | B | A |
| Com. Ex. 9 | A | C | A |

As shown in Table 2, the stripping solutions of Examples 1-6 are excellent in protecting metal wirings from corrosion, in protecting the interlevel films from damage and in stripping the post-ashing residues. In contrast, none of the stripping solutions of Comparative Examples 1-9 is excellent in the protection of the metal wirings and the interlevel films from corrosion and damage, and in the strippability of the post-ashing residues.

As discussed above in detail, the present invention provides a photoresist stripping solution which is excellent in protecting substrates having metal wirings (in particular, Cu wirings) formed thereon or substrates having both metal wirings and interlevel films formed thereon from corrosion and damage, and the strippability of photoresist layers and post-ashing residues. The present invention is particularly appropriately usable for stripping photoresist layers and post-ashing residues on substrates to be used in fabricating semiconductor devices.

What is claimed is:

1. A photoresist stripping solution comprising (a) a carboxyl group-containing acidic compound, (b) at least one basic compound selected from among alkanolamines and quaternary ammonium hydroxides represented by the following general formula (I): 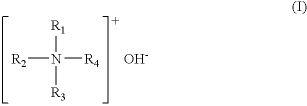
wherein R₁, R₂, R₃ and R₄ are each independently an alkyl group or a hydroxyalkyl group having 1-5 carbon atoms, (c) a sulfur-containing corrosion inhibitor and (d) water, and having a pH value of 3.5-5.5.

2. The photoresist stripping solution according to claim 1, wherein component (a) is a carboxylic acid containing an alkyl group or a hydroxyalkyl group having 1-5 carbon atoms.

3. The photoresist stripping solution according to claim 1, wherein component (a) is at least one member selected from among acetic acid, propionic acid and glycolic acid.

4. The photoresist stripping solution according to claim 1, wherein component (b) is at least one member selected from among monoethanolamine and tetraalkylammonium hydroxides.

5. The photoresist stripping solution according to claim 1, wherein component (c) is 1-thioglycerol.

6. The photoresist stripping solution according to claim 1 which has a pH value of 4.0-5.0.

7. A method of stripping photoresists comprising forming a photoresist pattern on a substrate, etching the substrate using said photoresist pattern as a mask, and thereafter stripping away the photoresist pattern from the substrate using the photoresist stripping solution according to any one of claims 1-6.

8. A method of stripping photoresists comprising forming a photoresist pattern on a substrate, etching the substrate using said photoresist pattern as a mask, then plasma ashing the photoresist pattern, and thereafter stripping away post-plasma ashing residues from the substrate using the photoresist stripping solution according to any one of claims 1-6.

9. The method of stripping photoresists according to claim 7, wherein the substrate has a metal wiring formed thereon or has both a metal wiring and an interlevel film thereon.

10. The method of stripping photoresists according to claim 8, wherein the substrate has a metal wiring formed thereon or has both a metal wiring and an interlevel film thereon.
